(19) United States
(12) Patent Application Publication
(10) Pub. No.: US 2008/0020520 A1
(43) Pub. Date: Jan. 24, 2008

(54) Method for manufacturing lower substrate of liquid crystal display device

(75) Inventors: Shiun-Chang Jan, Hsin-Chu (TW); Jia-Tzung Lee, Hsin-Chu (TW); Ko-Shin Kuo, Hsin-Chu (TW)

Correspondence Address: BACON & THOMAS, PLLC, 625 SLATERS LANE, FOURTH FLOOR, ALEXANDRIA, VA, 22314, US

(73) Assignee: AU Optronics Corp., Hsin-Chu (TW)

(21) Appl. No.: 11/723,034

(22) Filed: Mar. 16, 2007

(30) Foreign Application Priority Data
May 18, 2006 (TW) 095117642

(51) Int. Cl. H01L 21/84; H01L 21/00

(52) U.S. Cl. 438/149

(57) ABSTRACT

A method for improving the tapered angles of the insulating layer and the semiconductor layer of a lower substrate of a thin film transistor liquid crystal display device is disclosed. The method mainly applies an etching gas including a sulfur fluoride compound to etch the insulating layer. After etching, the tapered angle of the insulating layer is improved. Moreover, since the etching gas including a sulfur fluoride compound also results in lateral etching on the semiconductor layer, the step coverage of the subsequent process is improved, too. The method of the present invention can also be applied for manufacturing a multilayered thin film transistor containing a barrier layer, a semiconductor layer, and an insulating layer without delamination, breakage, or collapse. In addition, since the number of the used masks is reduced in the method of the present invention, the cost can be reduced and the process can be simplified.

### BACKGROUND OF THE INVENTION

1. Field of the Invention

The present invention relates to a method for manufacturing a thin film transistor (TFT), and more particularly, to a method for manufacturing a lower substrate of a liquid crystal display device.

2. Description of Related Art

A thin film transistor liquid crystal display (TFT-LCD) mainly comprises a thin film transistor (TFT) array substrate, a color filter substrate and a liquid crystal layer sandwiched therebetween. The TFT array substrate comprises plural pixels in an array, each of which comprises a TFT and a pixel electrode electrically connected to the TFT. The conventional method usually utilizes six or five mask steps to form gates, active regions, sources, drains, contact window regions of pads and pixel regions for manufacturing a TFT array substrate. Since the manufacturing process is time-consuming and complicated, many defects occur and the manufacturing cost increases. Hence, issues for reducing the mask steps and simplifying the process are very importance for manufacturing a TFT array substrate.

So far, there are many methods for reducing the number of mask steps to simplify the manufacturing process of a TFT array substrate. Some of the methods combine two mask steps into one mask step to complete the formation of films, and now become one of the important methods for reducing the number of masks and mask steps, since adjusting the sequence of steps without changing the specifications of the masks can reduce the number of masks.

In FIG. 1, there is shown a cross-section view of a thin film transistor manufactured by four mask steps in the conventional method. As shown, a gate layer 11, an insulating layer 12 and a semiconductor layer 13 are patterned first. Subsequently, a transparent electrode layer 15 is deposited. Finally, a source and a drain layer 16 are deposited.

The method combines the two mask steps of manufacturing a transparent electrode layer, a drain, and a source in the same mask step. Although the illustrated conventional method reduces the mask steps, the adhesion between the transparent electrode layer and the upper layer or the lower layer needs to be improved. For example, the difference of oxidation-reduction potential between the transparent electrode layer and the upper layer or the lower layer is so significant that film-delamination occurs.

For increasing the adhesion between the transparent electrode layer and the films in manufacturing, another process including steps for forming a barrier layer is disclosed to make the ohmic contact between the semiconductor layer and the transparent electrode layer well and further to improve the adhesion and the electric property.

FIGS. 2(a) to 2(e) are schematic views of the steps of the conventional manufacturing method. As shown, a first metal layer (gate) 21, an insulating layer 22, a semiconductor layer 23, an ohmic contact layer 24 and a barrier layer 25 are defined. As shown in FIG. 2(a), a patterned first metal layer (gate) 21 is formed over the substrate 2 first. Subsequently, an insulating layer 22, a semiconductor layer 23, an ohmic contact layer 24 and a barrier layer 25 are deposited in sequence to provide a multilayered structure as shown in FIG. 2(b).

Subsequently, as shown in FIG. 2(c), the barrier layer 25, the ohmic contact layer 24, and the semiconductor layer 23 are etched to form the transistor region. Since an etching stop layer may be formed in patterning the upper barrier layer 25, the tapered angles of the lower ohmic contact layer 24 and the semiconductor layer 23 are affected in patterning the semiconductor layer. Therefore, the tapered angle of the semiconductor layer is about 90°, as shown in FIG. 2(d).

The multilayered structure shown in FIG. 2(d) can improve the adhesion between films. However, the tapered angle is too large owing to the significant drop of the film-height in the multilayered structure. In the subsequent deposition of the transparent electrode layer 26, the source, and the drain layer (not shown), the over-large tapered angle of the insulating layer causes some defects, such as breakage or delamination, as shown in FIG. 2(e).

The yield of a TFT array substrate is mainly affected by the tapered angles of films. However, the tapered angles of most films formed by conventional etching are over the acceptable range. So far, some researchers suggest adjusting the parameters of the etching process to control the tapered angles. For example, the parameters of the etching process can be adjusted by using a special etching solution in wet etching or using a special etching gas in dry etching to achieve the improvement. However, the improved wet etching or dry etching still cannot meet the requirements of excellent tapered angles, reducing manufacturing cost, simplifying process, and/or mass production for manufacturing.

Hence, it is desirable to provide a manufacturing method of a lower substrate of an LCD device, which can form an excellent tapered angle to enhance step coverage, simplify the process to reduce the difficulty of manufacturing, and enhance the throughout and the yield.

### SUMMARY OF THE INVENTION

The object of the present invention is to provide a manufacturing method of a lower substrate of a TFT-LCD device, which can improve the tapered angles of the semiconductor layer and the insulating layer of a thin film transistor. In addition to forming an improved tapered angle of the insulating layer via dry etching, the barrier layer, the semiconductor layer, the insulating layer and the other layers in a multilayered structure can also be patterned via dry etching. The barrier layer can improve the electric property and the adhesion between layers and the insulating layer with an improved tapered angle can inhibit the formation of manufacturing defects in the following process. Furthermore, in the method of the present invention, the insulating layer in the light-penetrating region of the lower substrate of an LCD device can be etched thoroughly to enhance the light transmittance of the lower substrate and the improved tapered angles of the semiconductor layer and the insulating layer are formed.

The manufacturing method of a lower substrate of a LCD device of the present invention comprises the following steps: providing a substrate; forming a patterned first metal layer on the substrate; sequentially forming a first insulating layer and a semiconductor layer over the substrate, and patterning the semiconductor layer by a mask to form a transistor region; etching the first insulating layer and the patterned semiconductor layer laterally by an etching gas comprising a sulfur fluoride compound to form a tapered angle of the first insulating layer; sequentially forming a transparent electrode layer and a second metal layer over the transistor regions and the substrate; and defining a source and a drain in the transistor region, wherein the source and the drain individually contain the second metal layer without connecting to each other. The tapered angle of the first insulating layer of the present invention is 10° to 70°. Preferably, the tapered angle of the first insulating layer is 10° to 60°.

Accordingly, the present invention provides an improved tapered angle of the insulating layer of a thin film transistor to enhance the subsequent step coverage. Thereby, the electric property and the adhesion between layers are improved and the formation of pores between the layers of the thin film transistor is inhibited. The manufacturing method of a lower substrate of a LCD device of the present invention can form a laminate of a semiconductor layer and an insulating layer with an improved tapered angle, simplify the manufacturing process, reduce the number of masks by integrating manufacturing steps, and reduce the manufacturing cost.

The manufacturing method of a lower substrate of a TFT-LCD device of the present invention simplifies the conventional manufacturing process with six mask steps or five mask steps into a four-mask process by process integration. Patterning a gate layer, an insulating layer and a semiconductor layer first performs the manufacturing method of the present invention. Subsequently, a transparent electrode layer is deposited; and a drain layer, and a source layer are deposited finally. In the prior art, the transparent electrode layer, the drain layer, and the source layer are patterned via two mask steps, while in the method of the present invention, these layers illustrated above can be patterned in the same mask step for reducing the number of mask steps. Furthermore, the insulating layer in the light-penetrating region of the lower substrate can be etched thoroughly and thereby the light transmittance of the light-penetrating region of the lower substrate is enhanced.

The present invention provides a thin film transistor (TFT) for an LCD. The TFT of the present invention can further comprises a barrier layer locating between the semiconductor layer and the transparent electrode layer to enhance the electric property and the adhesion between an upper layer (such as a transparent electrode layer) and a lower layer (such as a semiconductor layer) to inhibit the poor electric property of the conventional thin film transistor caused by delamination. Thereby, the ohmic contact between the semiconductor layer and the transparent electrode layer is good, and the adhesion and electric property of following films are improved.

Accordingly, the manufacturing method of a lower substrate of a LCD device of the present invention comprises the following steps: providing a substrate; forming a patterned first metal layer on the substrate; sequentially forming a first insulating layer, a semiconductor layer, and a barrier layer over the substrate, and patterning the barrier layer and the semiconductor layer by a mask to form a transistor region; etching the first insulating layer and the patterned semiconductor layer laterally by an etching gas comprising a sulfur fluoride compound to form a tapered angle of the first insulating layer; sequentially forming a transparent electrode layer and a second metal layer over the transistor regions and the substrate; and defining a source and a drain in the transistor region, wherein the source and the drain individually contain the second metal layer without connecting to each other. The tapered angle of the first insulating layer of the present invention is 10° to 70°. Preferably, the tapered angle of the first insulating layer is 10° to 60°.

Since the manufacturing method of a lower substrate of a TFT-LCD device of the present invention can improve the tapered angle of the insulating layer of about 90° in the prior art to the tapered angle of 10° to 60°, the step coverage of the subsequent films is improved. In addition, although the thin film transistor of the present invention is a multilayered structure comprising a barrier layer, a semiconductor layer, and an insulating layer, the defects including delamination, breakage, and collapse do not occur. Thereby, the thin film transistor of the present invention has improved electric property.

In order to protect the thin film transistor from oxidation or from the influence of the following process, the manufacturing method of a lower substrate of an LCD device of the present invention can further comprise a step, forming a patterned second insulating layer in the transistor region after defining a source and a drain.

In the manufacturing method of the present invention, the content of the sulfur fluoride compound of the etching gas is not limited. Preferably, the etching gas comprises 40% or more content of the sulfur fluoride compound so as to etch the first insulating layer and the patterned semiconductor layer laterally. The etching gas can comprise any type of sulfur fluoride compounds. Preferably, the etching gas comprises sulfur hexafluoride, sulfur tetrafluoride, sulfur pentafluoride or a combination thereof. More preferably, the etching gas used for side-etching comprises sulfur hexafluoride.

In addition, the etching gas of the present invention can further comprise at least one auxiliary etching gas to control the process parameter such as the rate of etching, or pressure. The auxiliary etching gas can be a gas regulating the formation rate of fluorine atoms (e.g. O₂); a noble gas (e.g. Ar, He, or N₂); a fluorine-containing etching gas (e.g. CF₄, CHF₃, or C₂F₆); or a chlorine-containing etching gas (e.g. Cl₂, BCl₃ or HCl).

In the present invention, the flow ratio of the sulfur fluoride compound to the auxiliary etching gas can be regulated to meet the requirement of manufacturing. Preferably, the range of the flow ratio is 1:1 to 100:1 to improve the uniformity of the etched insulating layer. Thereby, the auxiliary etching gas of the present invention can be used for controlling the tapered angle of the insulating layer and the quality of etching. In the manufacturing method of the present invention, the transistor region of the present invention can comprise the first metal layer, which functions as a gate of the transistor region. In addition, after forming a semiconductor layer, an ohmic contact layer can be selectively formed on the semiconductor layer to make the ohmic contact between the semiconductor layer and the upper device layer well to enhance the electric property and the efficiency. The material of the ohmic contact layer can be any material suitable for a thin film transistor. Preferably, the material of the ohmic contact layer is N⁺ amorphous silicon.

Moreover, in the step for etching the first insulating layer and the patterned semiconductor layer laterally, the first insulating layer can be etched by dry plasma etching and the etched first insulating layer can be the first insulating layer outside the transistor regions. In etching the insulating layer of the present invention, the insulating layer in the light-penetrating region of the lower substrate can be etched thoroughly to enhance the transmittance of the lower substrate of a TFT-LCD device.

In etching the first insulating layer, the patterned semiconductor layer can be further etched laterally and a tapered angle of the semiconductor layer is formed; wherein the tapered angle is 10° to 70°. Preferably, the tapered angle of the semiconductor layer is 10° to 60°. Thereby, the etching gas can etch the semiconductor layer and the first insulating layer laterally, and the rate of etching the semiconductor layer is almost equal to that of etching the first insulating layer. Accordingly, the present invention can provide improved tapered angles of the semiconductor and the insulating layer to improve the stability of the following process.

In the manufacturing method of the present invention, the insulating layer and the semiconductor layer are etched laterally by the aforementioned step, and the ratio of tapered angles is not limited. Preferably, the ratio of tapered angles is 0.3 to 1.5.

In the step for defining a source and a drain in the transistor region, the second metal layer outside the transistor regions can be removed to define the drain and the source in the transistor region. Of course, the second metal layer outside the transistor region can also be maintained to serve as lines of a TFT array substrate or others.

In the present invention, the barrier layer, the semiconductor layer and the insulating layer can be formed by any process. Preferably, physical vapor deposition (e.g. ionized metal plasma physical vapor deposition (IMP-PVD)), chemical vapor deposition (e.g. plasma enhanced chemical vapor deposition, or thermal chemical vapor deposition), evaporation (e.g. metal evaporation), sputtering (e.g. collimated sputtering, or lone throw sputtering), or plating (e.g. electroplating, or electroless plating).

The material of the barrier layer is not restricted. Preferably, the material of the barrier layer is silicon oxide, silicon nitride, aluminum oxide, tantalum oxide, titanium nitride, indium-tin oxide, silicon carbide, nitrogen and oxygen doped silicon carbide, molybdenum, chromium, titanium, nickel, tungsten, ruthenium, cobalt, phosphorus, or combinations thereof. More preferably, the material of the barrier layer is silicon nitride (SiNx (Si₃N₄)), titanium nitride (TiN), indium-tin oxide (ITO), molybdenum, chromium, titanium, nickel, tungsten, ruthenium, cobalt, phosphorus, or combinations thereof. In the present invention, the barrier layer can be etched by dry etching or wet etching. In addition, after the barrier layer and the semiconductor layer are etched, the insulating layer is etched by dry etching to improve the tapered angles of the semiconductor layer and the insulating layer.

In the present invention, the substrate that can be applied in the method for manufacturing the lower substrate of a LCD device is not restricted. Preferably, the substrate is silicon substrate, glass substrate, or plastic substrate. More preferably, the substrate is a substrate used for an active matrix liquid crystal display device. For example, undoped silica glass, phosphorus doped glass (PSG), boron-phosphorus doped glass, soda-lime glass, borosilicate glass, sodium borosilicate glass, alkali-metal borosilicate glass, aluminosilicate glass, aluminoborosilicate glass, alkaline earth aluminoborosilicate glass, or combinations thereof can be used as a substrate.

The proper material used in the insulating layer of the manufactured TFT could be any insulating materials, and preferred to be organic materials, inorganic materials, or the combination thereof. More preferably, the proper material used in the insulating layer is silicon nitride (SiNₓ), silica (SiOₓ), silicon oxynitride (SiOₓN_{y}), or combination thereof. The second insulating layer of the present invention can be a passivation, an overcoat, or a multilayered combination thereof.

The material of the first metal layer, which is used for the gate of the TFT in the present invention, is not limited. Preferably, the material is aluminum, tungsten, chromium, copper, titanium, titanium nitride (TiNₓ), aluminum alloy, chromium alloy, molybdenum, or combinations thereof. The material of the second metal layer, which is used for the source and the drain of the TFT manufactured in the present invention is not limited. Preferably, the material is aluminum, tungsten, chromium, copper, titanium, titanium nitride, aluminum alloy, chromium alloy, molybdenum, or combinations thereof. The first metal layer and the second metal layer illustrated above can be monolayer or multilayered structures.

The proper materials of the semiconductor layer of the present invention could be any material of the semi-conductor layer. Preferably, the materials are amorphous silicon materials, or polymorphous silicon materials. Furthermore, the structure of the semiconductor layer is not limited. Preferably, the structure of the semiconductor layer is a multilayered structure, comprising a low-deposition-rate Si layer and a high-deposition-rate Si layer. Accordingly, the thickness and the electric property of the semiconductor layer in a multilayered structure can inhibit the following manufacturing defects.

The manufacturing method of a lower substrate of a LCD device is suitable for fabricating a conventional TFT comprising a semiconductor layer/an insulating layer; and a multilayered thin film structure comprising semiconductor layers/an insulating layer.

The present invention mainly uses an etching gas comprising a sulfur fluoride compound to etch the insulating layer. Thereby, an improved tapered angle of the insulating layer is formed and the semiconductor layer is etched laterally, and thereby the step coverage of the subsequent process is enhanced so as to inhibit the defects including breakage and collapse in manufacturing a transparent electrode layer, a source, a drain, a passivation and other layers. For this reason, the present invention can enhance the quantity of the thin film transistor and the stability of the process. In addition, the manufacturing cost is reduced by simplifying mask steps.

Other objects, advantages, and novel features of the invention will become more apparent from the following detailed description when taken in conjunction with the accompanying drawings.

### BRIEF DESCRIPTION OF THE DRAWINGS

FIG. 1 is a cross-section view of a thin film transistor manufactured by four mask steps in the conventional method.

FIGS. 2(a) to 2(e) are schematic views of manufacturing an insulating layer, a semiconductor layer, a barrier layer, and a transparent electrode layer of a thin film transistor of the conventional manufacturing method.

FIGS. 3(a) to 3(h) are schematic views of fabricating a lower substrate of a TFT-LCD device of an embodiment.

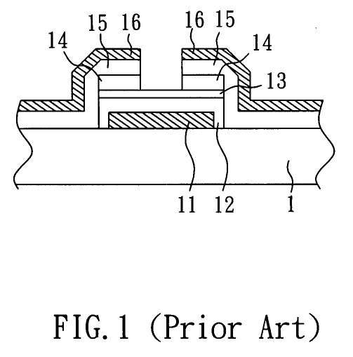

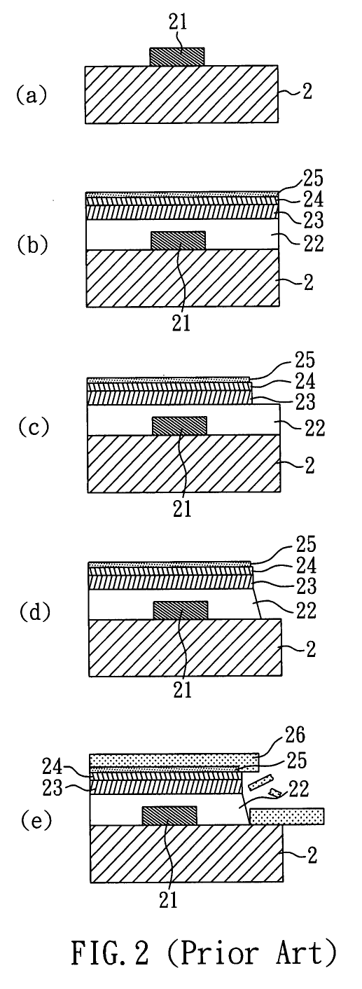

### DETAILED DESCRIPTION OF THE EMBODIMENT

### Embodiment 1

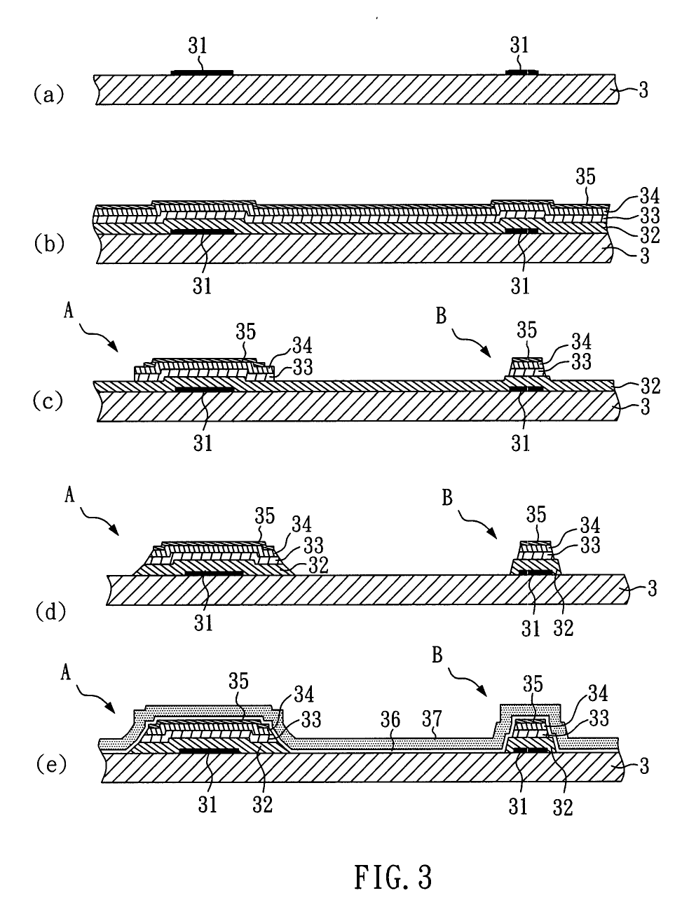

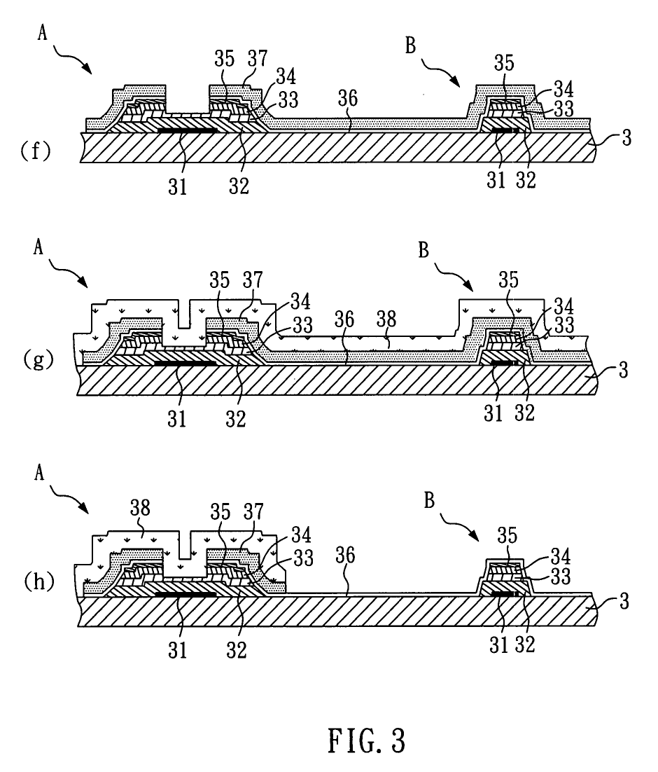

With reference to FIGS. 3(a) to 3(h), there are shown schematic views of fabricating a lower substrate of a liquid crystal display device of the present embodiment of the present invention. In the embodiment of the present invention, the lower substrate of a TFT-LCD device is prepared by four mask steps.

As shown in FIG. 3(a), a glass substrate 3 is prepared, and a first metal layer 31 is formed on the glass substrate 3. A pattern of the gate is defined by the first mask process and etching process. Preferably, the first metal layer 31 is composed of chromium alloy and molybdenum, and the structure can be a monolayer structure or a multilayered structure (not shown).

Then, as shown in FIG. 3(b), an insulating layer 32, a semiconductor layer 33, an ohmic contact layer 34, and a barrier layer 35 are deposited over the patterned first metal layer 31; wherein the insulating layer 32 is silicon oxide, the semiconductor layer 33 is amorphous silicon, the ohmic contact layer 34 is N⁺ amorphous silicon, and the barrier layer 35 is molybdenum. The ohmic contact layer 34 of the embodiment can make the ohmic contact between the semiconductor layer 33 and the upper device layer well to enhance the electric property and the efficiency.

As shown in FIGS. 3(c) and 3(d), a transistor region A and an auxiliary capacitance region B on the substrate 3 are defined by the second mask process and etching process. If necessary, a terminal block region on the substrate of a LCD device can be defined.

In the second mask process and etching process of the present embodiment, as shown in FIG. 3(c), the barrier layer 35 is patterned by dry or wet etching first. In the present invention, conventional wet etching is used to pattern the barrier layer 35. Then, the ohmic contact layer 34 and the semiconductor layer 33 are etched by dry etching so as to form the structure as shown in FIG. 3(c).

As shown in FIG. 3(d), the subsequent process for etching the insulating layer 32 is performed by an etching gas comprising SF₆. After patterning the insulating layer 32 by dry etching, the tapered angle of the insulating layer is about 40°. Herein, the patterned ohmic contact layer 34 and the patterned semiconductor layer 33 are further etched in the horizontal direction (side-etched), so as to form a tapered angle of about 55°. Therefore, an ideal tapered angle is formed, resulting from a taper configuration constructed by the semiconductor layer 33 and the insulating layer 32, and thereby the adhesion of the following film is improved.

In the present embodiment, the ratio of the tapered angle of the insulating layer to that of the semiconductor is 0.7 to 1.5 by an etching gas comprising SF₆ with the ability of side-etching. In a more detailed description, the ratio of tapered angle of the insulating layer to that of the semiconductor is about 0.7.

In etching of the present embodiment, the insulating layer without being protected by photoresist would be etched thoroughly, wherein the insulating layer in the light-penetrating region of the substrate is also etched to enhance the light transmittance of the light-penetrating region.

In the present embodiment, the insulating layer 32 is also patterned by dry etching, so the ohmic contact layer 34, the semiconductor layer 33 and the insulating layer 32 can be patterned in the same machine to reduce the manufacturing cost and to inhibit the formation of manufacturing defects caused by changing the fabrication process.

In etching the insulating layer 32, the flow, the RF power and the pressure of a etching gas can affect the tapered angle of the insulating layer. For example, when the flow of the etching gas increases by 100 sccm (standard cubic centimeter per), the tapered angle of the insulating layer reduces by 0.5-1.0. Therefore, the process parameters of etching the insulating layer 32 can be regulated to achieve an optimal manufacturing condition.

As shown in FIG. 3(e), a transparent electrode layer 36 (e.g. indium-zinc oxide, indium-tin oxide, or indium-tin-zinc oxide), and a second metal layer 37 (e.g. molybdenum) are deposited over the substrate 3, the transistor region A, and the auxiliary capacitance region B.

As shown in FIG. 3(f), a source and a drain in the transistor region A is defined by the third mask process and etching process to establish the structure of the transistor region A and the structure of the auxiliary capacitance region B completely. Herein, a barrier layer 35 forms between the transparent electrode layer 36 and the semiconductor layer 33 to function as an adhesion layer. Therefore, the delamination and poor contact caused by the difference of film properties between the two layers are inhibited so as to afford a thin film transistor with improved electric property.

In order to protect the transistor region A from oxidation, as shown in FIGS. 3(g) and 3(h), a second insulating layer 38 is formed and then patterned by the forth mask process and etching process, and the second metal layer 37 in the light-penetrating region of the substrate is removed. Herein, the second insulating layer 38 can be a passivation, an overcoat or a multilayered combination thereof. In the present embodiment, the second insulating layer 38 is a passivation of silicon nitride.

In the present embodiment, four mask steps to reduce the manufacturing cost can fabricate the lower substrate of a TFT-LCD device. Furthermore, the insulating layer in the light-penetrating region of the substrate is etched thoroughly to enhance the light transmittance of the substrate.

### Embodiment 2

In the present embodiment, the manufacturing process of a lower substrate of a TFT-LCD device is the same as that of Embodiment 1 using a four-stage mask process, except that the semiconductor layer is a multilayer structure and the etching condition of the insulating layer is modified.

The semiconductor layer of the present embodiment is a multilayered structure comprising a low-deposition-rate Si layer and a high-deposition-rate Si layer. The multilayer structure of the lower substrate is established by depositing a first metal layer, a first insulating layer, a low-deposition-rate Si layer, a high-deposition-rate Si layer, an ohmic contact layer, and a barrier layer in sequence over the substrate.

In the present embodiment, forming a high-deposition-rate Si layer can reduce the time of depositing a semiconductor layer and increase the efficiency of manufacturing a lower substrate. In addition, the high-deposition-rate Si layer can thicken the semiconductor layer and also be an etching stop layer to inhibit shorting between elements caused by over-etching and thereby forming defects.

Furthermore, in etching the insulating layer of the present embodiment, the etching gas mixture including SF₆ having the ability of etching the semiconductor layer laterally, and a gas for regulating the formation rate of fluorine atoms, a noble gas, a fluorine-containing etching gas, or a chlorine-containing etching gas, is used.

The etching gas can improve the tapered angle of the insulating layer and further control the quality of etching, such as etching rate and uniformity. In the present embodiment, the flow ratio of the SF₆ having the ability of etching the semiconductor layer laterally to the auxiliary etching gas can be regulated to about 10:1 so as to provide a tapered angle and quality of etching. In the present invention, the flow ratio of the sulfur fluoride compound to the auxiliary etching gas can be regulated to meet the requirement of manufacturing. Preferably, the range of ratio is 1:1 to 100:1 to improve the uniformity of the etched insulating layer. Accordingly, the tapered angle of the insulating layer of the present embodiment is improved to 10°-55°, and the ratio of tapered angles of the insulating layer to the semiconductor layer is controlled in a range of 0.3-1.1.

The auxiliary etching gas used in the embodiment and the function thereof are described as the following:

A gas regulating the formation rate of fluorine atoms (e.g. O₂) is used to react with SF₆ to increase or decrease the formation rate of fluorine atoms and thereby the tapered angle of the insulating layer is controlled. For example, the addition of oxygen would increase the formation rate of fluorine atoms. When the flow of oxygen increases by 100 sccm (standard cubic centimeter per minute), the tapered angle of the insulating layer decreases by 0.5° to 15°. Furthermore, the flow ratio of the sulfur fluoride compound (such as SF₆) to the auxiliary etching gas (O₂) is about 25:1. Undoubtedly, the condition is not limited to those. Preferably, the flow ratio is 1:1 to 50:1. More preferably, the flow ratio is 3:1 to 100:1.

A noble gas including Ar, He, or N₂ is used for regulating the pressure of a gas in the present invention. In the present embodiment, Ar is used as a regulating gas. The pressure of a gas for etching the insulating layer significantly affects the tapered angle of the insulating layer. When the pressure of the etching gas increases by 10 mTorr, the tapered angle of the insulating layer decreases by 0.5° to 10°. The flow ratio of the etching gas with the ability of side-etching (such as SF₆) to the auxiliary etching gas (Ar) is about 50:1. The condition is not limited to those. Preferably, the flow ratio is 1:1 to 100:1. More preferably, the flow ratio is 30:1 to 90:1.

A fluorine-containing etching gas including CF₄, CHF₃, or C₂F₆ is used for forming products on the surface of the film in etching to regulate the tapered angle of the insulating layer. In the step for etching the insulating layer, the auxiliary etching gas of CF₄ reacts with the surface of the insulating layer to form a carbonized polymer. When the flow of the fluorine-containing etching gas increases by 100 sccm, the tapered angle of the insulating layer decreases by 0.5° to 10°. In the present embodiment, the flow ratio of the sulfur fluoride compound (such as SF₆) to the auxiliary etching gas (CF₄) is about 80:1. The condition is not limited to those. Preferably, the flow ratio is 1:1 to 100:1. More preferably, the flow ratio is 30:1 to 90:1 to avoid too many products formed on the surface of the insulating layer to increase the tapered angle and decrease the rate of etching the insulating layer.

A chlorine-containing etching gas including Cl₂, BCl₃ or HCl is used for decreasing the rate of etching the insulating layer to thereby decrease the tapered angle. When the flow of the chlorine-containing etching gas increases by 100 sccm, the tapered angle of the insulating layer decreases by 0.5° to 30°. Because the decrease in the tapered angle of the insulating layer is larger, the ratio of tapered angles of the insulating layer to the semiconductor layer decreases to 0.3-0.8. In the present embodiment, the flow ratio of the sulfur fluoride compound (such as SF₆) to the auxiliary etching gas (Cl₂ or HCl) is about 80:1. The condition is not limited to those. Preferably, the flow ratio is 1:1 to 100:1. More preferably, the flow ratio is 30:1 to 90:1 to avoid the rate of etching the insulating layer too slow.

### Embodiment 3

In the present embodiment, the manufacturing process of a lower substrate of a TFT-LCD device is the same as that of Embodiment 2 with a four-stage mask process, except that the semiconductor layer is a monolayer structure illustrated in Embodiment 1, and the others, such as the etching gas and the other layer structures of the transistor are similar to those in Embodiment 2.

### Embodiment 4

In the present embodiment, the manufacturing process of a lower substrate of a TFT-LCD device is the same as that of Embodiment 2 with a four-stage mask process, except that a barrier layer is not formed in the structure of the transistor, and the others, such as the etching gas and the other layer structures of the transistor are similar to those in Embodiment 2.

According to the description illustrated above, the present invention can improve the tapered angles of the insulating layer and the semiconductor layer to 10° to 60°, while the tapered angle in the conventional art is around 90°. In addition, using a different etching gas and condition can control the tapered angle of the insulating layer of the present invention.

Thereby, in the present invention, the manufacturing method of a lower substrate of a TFT-LCD device can enhance the performance of the transistor, the process stability and the transmittance of the light-penetrating region. Furthermore, the manufacturing cost can be reduced by the simplification of mask process.

Although the present invention has been explained in relation to its embodiment, it is to be understood that many other possible modifications and variations can be made without departing from the spirit and scope of the invention as hereinafter claimed.

What is claimed is:

1. A method for manufacturing a lower substrate of a liquid crystal display device, comprising:
providing a substrate;
forming a patterned first metal layer on the substrate;
forming a first insulating layer, a semiconductor layer, and a barrier layer over the substrate, and patterning the barrier layer and the semiconductor layer by a mask to form a transistor region;
etching the first insulating layer and the patterned semiconductor layer laterally by an etching gas comprising a sulfur fluoride compound to form a tapered angle of the first insulating layer, wherein the range of the tapered angle is 10° to 70°;
forming a transparent electrode layer and a second metal layer over the transistor region and the substrate; and
defining a source and a drain in the transistor region, wherein the source and the drain individually contain the second metal layer without connecting to each other.

2. The method of claim 1, further comprising a step, forming a patterned second insulating layer in the transistor region after defining the source and the drain.

3. The method of claim 1, wherein the content of the sulfur fluoride compound of the etching gas is 40% or more.

4. The method of claim 1, wherein the sulfur fluoride compound is sulfur hexafluoride, sulfur tetrafluoride, sulfur pentafluoride or a combination thereof.

5. The method of claim 1, wherein the etching gas further comprises at least one auxiliary etching gas, and the auxiliary etching gas is O₂, Ar, He, N₂, CF₄, CHF₃, C₂F₆, Cl₂, BCl₃, or HCl.

6. The method of claim 5, wherein the flow ratio of the sulfur fluoride compound to the auxiliary etching gas of the etching gas is 1/1 to 100/1.

7. The method of claim 1, wherein the tapered angle of the first insulating layer is 10° to 60°.

8. The method of claim 1, wherein the transistor region comprises the first metal layer.

9. The method of claim 1, further forming an ohmic contact layer on the semiconductor layer after forming the semiconductor layer.

10. The method of claim 1, wherein the step for etching the first insulating layer and the patterned semiconductor layer laterally is performed by dry etching.

11. The method of claim 1, wherein the etched first insulating layer is the first insulating layer outside the transistor region.

12. The method of claim 1, wherein a tapered angle of the semiconductor layer is formed and the tapered angle is 10° to 70° after etching the first insulating layer.

13. The method of claim 1, wherein the ratio of tapered angles of the insulating layer to the semiconductor is 0.3 to 1.5.

14. A method for manufacturing a lower substrate of a liquid crystal display device, comprising the steps:
providing a substrate;
forming a patterned first metal layer on the substrate;
forming a first insulating layer and a semiconductor layer over the substrate, and patterning the semiconductor layer by a mask to form a transistor region;
etching the first insulating layer and the patterned semiconductor layer laterally by a etching gas including a sulfur fluoride compound to form a tapered angle of the first insulating layer, wherein the range of the tapered angle is 10° to 70°;
forming a transparent electrode layer and a second metal layer over the transistor region and the substrate; and
defining a source and a drain in the transistor region, wherein the source and the drain individually contain the second metal layer without connecting to each other.

15. The method of claim 14, further comprising a step, forming a patterned second insulating layer in the transistor region after defining the source and the drain.

16. The method of claim 14, wherein the content of the sulfur fluoride compound of the etching gas is 40% or more.

17. The method of claim 14, wherein the sulfur fluoride compound is sulfur hexafluoride, sulfur tetrafluoride, sulfur pentafluoride or a combination thereof.

18. The method of claim 14, wherein the etching gas further comprises at least one auxiliary etching gas, and the auxiliary etching gas is O₂, Ar, He, N₂, CF₄, CHF₃, C₂F₆, Cl₂, BCl₃, or HCl.

19. The method of claim 18, wherein the flow ratio of the sulfur fluoride compound to the auxiliary etching gas of the etching gas is 1/1 to 100/1.

20. The method of claim 14, wherein the tapered angle of the first insulating layer is 10° to 60°.

21. The method of claim 14, wherein the transistor region comprises the first metal layer.

22. The method of claim 14, further forming an ohmic contact layer on the semiconductor layer after forming the semiconductor layer.

23. The method of claim 14, wherein the step for etching the first insulating layer and the patterned semiconductor layer laterally is performed by dry etching.

24. The method of claim 14, wherein the etched first insulating layer is the first insulating layer beyond the transistor region.

25. The method of claim 14, wherein a tapered angle of the semiconductor layer is formed and the tapered angle is 10° to 70° after etching the first insulating layer.

26. The method of claim 14, wherein the ratio of tapered angles of the insulating layer to the semiconductor is 0.3 to 1.5.
